(19) United States
(12) Patent Application Publication
(10) Pub. No.: US 2003/0146500 A1
(43) Pub. Date: Aug. 7, 2003

(54) Package for semiconductor device with ground lead connection having high stress resistance

(75) Inventors: Battista Vitali, Romano Di Lombardia (IT); Roberto Tiziani, Nerviano (IT); Loic Renard, Agrate Brianza (IT)

Correspondence Address: MODIANO & ASSOCIATI, Via Meravigli, 16, MILANO, 20123, IT

(73) Assignee: STMicroelectronics S.R.L.

(21) Appl. No.: 10/061,221

(22) Filed: Feb. 4, 2002

(51) Int. Cl. H01L 23/48

(52) U.S. Cl. 257/692; 257/693

(57) ABSTRACT

A package for a semiconductor device, comprising a leadframe on which at least one semiconductor chip is arranged, the semiconductor chip being connected to the leadframe by conducting leads and at least one ground lead; the ground lead is connected between the top of the semiconductor chip and a recessed region of the leadframe.

### BACKGROUND OF THE INVENTION

The present invention relates to a package for a semiconductor device with ground leads having a high resistance to stresses.

It is known that the package for a semiconductor device is constituted by a conducting frame or leadframe, on which the chip is placed; the chip is in turn encapsulated in resin.

The connection between the semiconductor chip and the leadframe occurs by means of connecting leads, which can be made of copper or for example of gold, and with the presence of at least one ground lead.

The connection of the conducting leads and of the ground lead occurs between metallized areas formed on the leadframe and corresponding areas within the semiconductor chip.

The packages of semiconductor devices are subjected, after manufacture, to intensive thermal cycles aimed at testing their reliability, so as to simulate the actual life duration of a semiconductor chip, in order to reject batches of packages that may be defective.

One problem that arises with the thermal cycles to which semiconductor device packages are subjected is the fact that the conducting leads are currently soldered at a recessed area of the leadframe, while the ground leads are connected at a region that protrudes from said leadframe. Substantially, the leadframe has a tooth or projection that protrudes with respect to the plane of the leadframe, and the ground leads are connected on said projection.

This solution, disclosed for example in U.S. Pat. No. 5,229,918 by SGS-Thomson Microelectronics S.R.L. has, as mentioned, drawbacks as regards the thermal cycles to which the packages are to be subjected.

During these reliability tests for qualification of production batches, the ground leads are in fact connected, as mentioned, between the top of the chip and the leadframe, i.e., the region where the chip is attached. This area is absolutely flat and is easily subject to delamination.

During thermal cycles, the difference between the thermal expansion coefficients of the copper or gold filaments that constitute the ground leads, the copper that constitutes the leadframe and the resin that encapsulates the semiconductor chip produces a relative displacement which causes cracks and essentially electrically opens the circuit. Accordingly, the ground leads become unsoldered from the leadframe and in particular from the protruding tooth on which they are connected.

### SUMMARY OF THE INVENTION

The aim of the present invention is to provide a package for a semiconductor device in which the useful life of the ground leads is substantially longer than that of the ground leads used in conventional packages, when the packages are subjected to thermal cycles for their reliability testing.

Within this aim, an object of the present invention is to provide a package for a semiconductor device in which the ground leads are not subject to damage when they are subjected to thermomechanical stresses.

Another object of the present invention is to provide a package for a semiconductor device that can be employed both when using copper conducting leads and when using gold conducting leads.

Another object of the present invention is to provide a package for a semiconductor device that is highly reliable, relatively simple to manufacture and at competitive costs.

This aim and these and other objects that will become better apparent hereinafter are achieved by a package for a semiconductor device, comprising a leadframe on which at least one semiconductor chip is arranged, said semiconductor chip being connected to said leadframe by means of conducting leads and at least one ground lead, characterized in that said ground lead is connected between the top of said semiconductor chip and a recessed region of said leadframe.

### BRIEF DESCRIPTION OF THE DRAWINGS

Further characteristics and advantages of the invention will become better apparent from the description of a preferred but not exclusive embodiment of the package for semiconductor device according to the present invention, illustrated only by way of non-limitative example in the accompanying drawings, wherein:

FIG. 1 is a side elevation view of a package for semiconductor device of a known type; and

FIG. 2 is a schematic side elevation view of a package for semiconductor device according to the present invention.

### DESCRIPTION OF THE PREFERRED EMBODIMENTS

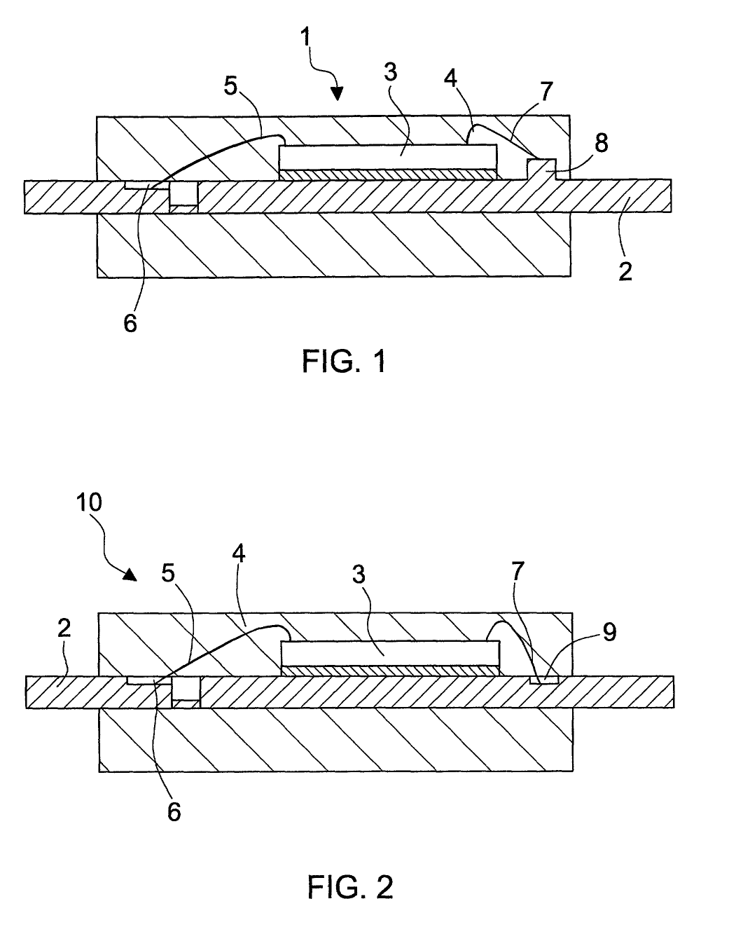

With reference to the figures, in which identical reference numerals designate identical elements, the semiconductor package of the known type already disclosed earlier and shown in FIG. 1 is first described briefly.

Substantially, the package for semiconductor device shown in FIG. 1 and generally designated by the reference numeral 1 comprises a leadframe 2 on which a semiconductor chip 3 encapsulated in a resin compound 4 is arranged. The semiconductor chip 3 is connected to the leadframe by means of conducting leads 5, which are connected at one end to the top of the semiconductor chip 3 and at the other end at a recessed region 6 of the leadframe.

The ground lead 7 is instead connected between the top of the semiconductor chip 3 and a tooth-like protruding portion 8 of the leadframe 2.

This solution, as explained earlier, causes problems to the ground leads during thermal cycles.

The package for semiconductor device according to the present invention is illustrated with reference to FIG. 2 and is now generally designated by the reference numeral 10. The particularity of the invention consists of the fact that the ground leads 7 are now connected between the semiconductor chip 3 and the leadframe 2 not by using a tooth that protrudes from the leadframe 2 but by providing this connection at a hole or generally recessed region 9 formed in the leadframe 2.

In this manner, the connection of the ground leads 7 is provided in a manner similar to the one used for the conducting leads 5.

The solution of providing in the leadframe 2 a hole or recessed region 9 to which one end of the ground leads 7 is to be connected (the other end being connected to the top of the semiconductor chip) allows to prevent the ground leads from being subject, during thermal package testing cycles, to the breakages that are frequent in known types of package.

Conveniently, the recess or hole 9 formed at the leadframe 2 can be preferably in an interval between 0.05 and 0.15 mm.

The connection of the ground leads at the recessed region 9 of the leadframe 2 can be used both for copper ground leads and for gold ground leads.

The invention thus provides a technical solution that is openly in contrast with the teachings of the previously cited prior U.S. Pat. No. 5,229,918, which instead teaches to connect the ground leads at a raised region (tooth) of the leadframe.

The connection of the conducting leads in the recessed cavity 9 allows to subject the package for semiconductor devices to all the thermal cycles required to identify possible defects thereof, without damaging the connection of the ground lead, as occurs in thermal cycles to which known types of package are subjected.

In practice it has been found that the package according to the present invention fully achieves the intended aim and objects, since it allows to provide a connection of the ground leads that is durable and not subject to breakages caused by the thermal cycles to which package batches are subjected in order to identify any reliability problems thereof.

The invention thus conceived is susceptible of numerous modifications and variations, all of which are within the scope of the inventive concept; all the details may further be replaced with other technically equivalent elements.

In practice, the materials used, so long as they are compatible with the specific aim, as well as the contingent shapes and dimensions, may be any according to requirements and to the state of the art.

What is claimed is:

1. A package for a semiconductor device, comprising a leadframe on which at least one semiconductor chip is arranged, said semiconductor chip being connected to said leadframe by means of conducting leads and at least one ground lead, wherein said ground lead is connected between the top of said semiconductor chip and a recessed region of said leadframe.

2. The package according to claim 1, wherein said recessed region is formed by a hole in said leadframe.

3. The package according to claim 1, wherein said recessed region is formed by a depressed area of said leadframe.

4. The package according to claim 1, wherein said recessed region of said leadframe has a depression whose dimensions are between 0.05 and 0.15 mm.

5. The package according to claim 1, wherein said leadframe and said semiconductor chip are encapsulated in a resin compound.

6. The package according to claim 1, wherein said conducting leads and the ground leads are made of copper.

7. The package according to claim 1, wherein said conducting leads and the ground leads are made of gold.

8. The package according to claim 1, wherein said leadframe is made of copper.

9. A package for a semiconductor device, comprising a leadframe on which at least one semiconductor chip is arranged, said semiconductor chip being connected to said leadframe by means of conducting leads and by means of at least one ground lead, wherein said conducting leads and said at least one ground lead are connected at recessed regions of said leadframe.

10. The package according to claim 9, wherein said recessed regions of said leadframe are depressed with respect to the upper surface of said leadframe on which said semiconductor chip is rested.
